(19) United States
(12) Patent Application Publication
(10) Pub. No.: US 2025/0098074 A1
(43) Pub. Date: Mar. 20, 2025

(54) MITIGATING FIBER WEAVE EFFECT IN A PRINTED CIRCUIT BOARD

(71) Applicant: Dell Products L.P., Round Rock, TX (US)

(72) Inventors: Bhyrav M. Mutnury, Round Rock, TX (US); Sandor Tibor Farkas, Round Rock, TX (US)

(21) Appl. No.: 18/469,991

(22) Filed: Sep. 19, 2023

(51) Int. Cl. H05K 3/00; H05K 1/03

(52) U.S. Cl. CPC H05K 3/0044; H05K 1/038; H05K 2203/0228

(57) ABSTRACT

Mitigating fiber weave effect, including obtaining a laminate sheet, the laminate sheet including a fiber weave of fibers; obtaining a cut laminate sheet from the laminate sheet, the laminate sheet including a first side and a second side opposite to the first side, the obtaining including: marking multiple cutting line between the first side and the second side of the laminate sheet positioning a printed circuit board (PCB) design image in superimposition with the cut laminate sheet; rotating the cut laminate sheet such that each of the sides of the cut laminate sheet are aligned with a respective side of the PCB design image; and forming the PCB on the cut laminate sheet based on the rotation of the cut laminate sheet with respect to the PCB design image and the alignment between the cut laminate sheet and the PCB design image.

### BACKGROUND

### Field of the Disclosure

The disclosure relates generally mitigating fiber weave effect in a printed circuit board.

### Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

### SUMMARY

Innovative aspects of the subject matter described in this specification may be embodied in a method of mitigating fiber weave effect, including obtaining a laminate sheet, the laminate sheet including a fiber weave of fibers extending in a direction between a first side of the laminate sheet and a second side of the laminate sheet, the first side of the laminate sheet opposite to the second side of the laminate sheet; obtaining a cut laminate sheet from the laminate sheet, the laminate sheet including a first side and a second side opposite to the first side, the obtaining including: marking a first cutting line between the first side and the second side of the laminate sheet, the first cutting line at an angle with respect to the direction of the fibers of the laminate sheet; marking a second cutting line between the first side and the second side of the laminate sheet, the second cutting line spaced-apart from the first cutting line and parallel to the first cutting line; marking a third cutting line extending between the first and the second cutting lines, the third cutting line perpendicular to the first and the second cutting lines; marking a fourth cutting line extending between the first and the second cutting lines, the fourth cutting line spaced-apart from the third cutting line and parallel to the third cutting line; cutting the laminate sheet at the first, second, third, and fourth cutting lines to form first, second, third, and four sides, respectively, of the cut laminate sheet; positioning a printed circuit board (PCB) design image in superimposition with the cut laminate sheet; rotating the cut laminate sheet such that each of the sides of the cut laminate sheet are aligned with a respective side of the PCB design image; and forming the PCB on the cut laminate sheet based on the rotation of the cut laminate sheet with respect to the PCB design image and the alignment between the cut laminate sheet and the PCB design image.

Other embodiments of these aspects include corresponding systems and apparatus.

These and other embodiments may each optionally include one or more of the following features. For instance, marking the first cutting line includes marking the first cutting line such that the angle with respect to the direction of the fibers of the laminate sheet is approximately 8 degrees. A width distance between the third cutting line and the fourth cutting line of the cut laminate sheet is less than a width distance between the first side and the second side of the laminate sheet. The third cutting line extends from the first cutting line at the first side of the laminate sheet to the second cutting line, wherein an end of the third cutting line at the second cutting line is spaced-apart from the first side of the laminate sheet a distance. The fourth cutting line extends from the first cutting line, spaced-apart from the second side of the laminate sheet the distance, to the second cutting line, wherein an end of the fourth cutting line at the second cutting line is at the second side of the laminate sheet. The PCB design image includes at least one differential pair of traces extending between a first side of the PCB design image and a second side of the PCB design image, the second side of the PCB design image opposite to the first side of the PCB design image, wherein the PCB design image includes a third side and a fourth side extending between the first and the second sides of the PCB design image, the third side of the PCB design image opposite to the fourth side of the PCB design image, wherein cutting the laminate sheet further includes: cutting the laminate sheet at the first cutting line to form the first side of the cut laminate sheet; cutting the laminate sheet at the second cutting line to form the second side of the cut laminate sheet; cutting the laminate sheet at the third cutting line to form the third side of the cut laminate sheet; cutting the laminate sheet at the fourth cutting line to form the fourth side of the cut laminate sheet, wherein rotating the cut laminate sheet further includes: rotating the cut laminate sheet such that: the first side of the cut laminate sheet is aligned with the third side of the PCB design image; the second side of the cut laminate sheet is aligned with the fourth side of the PCB design image; the third side of the cut laminate sheet is aligned with the first side of the PCB design image; and the fourth side of the cut laminate sheet is aligned with the second side of the PCB design image. Rotating the cut laminate sheet further includes rotating the cut laminate sheet such that each of the sides of the cut laminate sheet are aligned with a respective side of the PCB design image and the differential pair of traces extend between the third side and the fourth side of the cut laminate sheet at the angle with respect to the fibers of the cut laminate sheet. After obtaining the cut laminate sheet, the method further including: obtaining an additional cut laminate sheet from the laminate sheet, the additional laminate sheet including a first side and a second side opposite to the first side, the obtaining including: marking a fifth cutting line between the first side and the second side of the laminate sheet, the fifth cutting line at the angle with respect to the direction of the fibers of the laminate sheet; marking a sixth cutting line between the first side and the second side of the laminate sheet, the sixth cutting line spaced-apart from the fifth cutting line and parallel to the fifth cutting line; marking a seventh cutting line extending between the fifth and the sixth cutting lines, the seventh cutting line perpendicular to the fifth and the sixth cutting lines; marking an eighth cutting line extending between the fifth and the sixth cutting lines, the eighth cutting line spaced-apart from the seventh cutting line and parallel to the seventh cutting line; cutting the laminate sheet at the fifth, sixth, seventh, and eighth cutting lines to form fifth, sixth, seventh, and eighth sides, respectively, of the additional cut laminate sheet; positioning the PCB design image in superimposition with the additional cut laminate sheet; rotating the additional cut laminate sheet such that each of the sides of the additional cut laminate sheet are aligned with a respective side of the PCB design image; and forming an additional PCB on the additional cut laminate sheet based on the rotation of the additional cut laminate sheet with respect to the PCB design image and the alignment between the additional cut laminate and the PCB design image. The fifth cutting line is the same as the fourth cutting line. After obtaining the cut laminate sheet, the method further including: identifying an additional PCB design image, the additional PCB design image including at least one differential pair of traces extending between a first side of the additional PCB design image and a second side of the additional PCB design image, the second side of the additional PCB design image opposite to the first side of the additional PCB design image; obtaining an additional cut laminate sheet from the laminate sheet, the additional laminate sheet including a first side and a second side opposite to the first side, the obtaining including: marking a fifth cutting line between the first side and the second side of the laminate sheet, the fifth cutting line at the angle with respect to the direction of the fibers of the laminate sheet; marking a sixth cutting line between the first side and the second side of the laminate sheet, the sixth cutting line spaced-apart from the fifth cutting line and parallel to the fifth cutting line; marking a seventh cutting line extending between the fifth and the sixth cutting lines, the seventh cutting line perpendicular to the fifth and the sixth cutting lines; marking an eighth cutting line extending between the fifth and the sixth cutting lines, the eighth cutting line spaced-apart from the seventh cutting line and parallel to the seventh cutting line; cutting the laminate sheet at the fifth, sixth, seventh, and eighth cutting lines to form fifth, sixth, seventh, and eighth sides, respectively, of the cut laminate sheet; positioning the PCB design image in superimposition with the additional cut laminate sheet; rotating the additional cut laminate sheet such that each of the sides of the additional cut laminate sheet are aligned with a respective side of the additional PCB design image; and forming an additional PCB, including the differential pair of traces, on the additional cut laminate sheet based on the rotation of the additional cut laminate sheet with respect to the additional PCB design image and the alignment between the additional cut laminate and the additional PCB design image. The fifth cutting line is the same as the second cutting line. The additional PCB design image differs from the PCB design image.

Particular implementations of the subject matter described in this specification can be implemented so as to realize one or more of the following advantages. For example, when generating PCBs using laminate sheets, generating a cut laminate sheet from a larger laminate roll by angling the cuts on the laminate roll reduces waste of the laminate roll.

The details of one or more embodiments of the subject matter described in this specification are set forth in the accompanying drawings and the description below. Other potential features, aspects, and advantages of the subject matter will become apparent from the description, the drawings, and the claims.

### BRIEF DESCRIPTION OF DRAWINGS

FIG. 1 is a block diagram of selected elements of an embodiment of an information handling system.

FIG. 2 illustrates a block diagram of an information handling system including a printed circuit board (PCB).

FIG. 3 illustrates a simplified top down view of a PCB design image used in forming the PCB.

FIG. 4 illustrates a portion of a roll of a laminate sheet.

FIG. 5 illustrates a flowchart for mitigating fiber weave effect in the PCB.

FIG. 6 illustrates the laminate sheet.

FIG. 7 illustrates a cut laminate sheet.

FIG. 8 illustrates the PCB design image in superimposition with a rotated cut laminate sheet.

### DESCRIPTION OF PARTICULAR EMBODIMENT(S)

This disclosure discusses mitigating fiber weave effect in a printed circuit board. Specifically, this disclosure discusses mitigating fiber weave effect, including identifying a printed circuit board (PCB) design image, the PCB design image including at least one differential pair of traces extending between a first side of the PCB design image and a second side of the PCB design image, the second side of the PCB design image opposite to the first side of the PCB design image; obtaining a laminate sheet, the laminate sheet including a fiber weave of fibers extending in a direction between a first side of the laminate sheet and a second side of the laminate sheet, the first side of the laminate sheet opposite to the second side of the laminate sheet; obtaining a cut laminate sheet from the laminate sheet, the laminate sheet including a first side and a second side opposite to the first side, the obtaining including: marking a first cutting line between the first side and the second side of the laminate sheet, the first cutting line at an angle with respect to the direction of the fibers of the laminate sheet; marking a second cutting line between the first side and the second side of the laminate sheet, the second cutting line spaced-apart from the first cutting line and parallel to the first cutting line; marking a third cutting line extending between the first and the second cutting lines, the third cutting line perpendicular to the first and the second cutting lines; marking a fourth cutting line extending between the first and the second cutting lines, the fourth cutting line spaced-apart from the third cutting line and parallel to the third cutting line; cutting the laminate sheet at the first, second, third, and fourth cutting lines to form first, second, third, and four sides, respectively, of the cut laminate sheet; positioning the PCB design image in superimposition with the cut laminate sheet; rotating the cut laminate sheet such that each of the sides of the cut laminate sheet are aligned with a respective side of the PCB design image; and forming a printed circuit board (PCB), including the differential pair of traces, on the cut laminate sheet based on the rotation of the cut laminate sheet with respect to the PCB design image and the alignment between the cut laminate sheet and the PCB design image.

In the following description, details are set forth by way of example to facilitate discussion of the disclosed subject matter. It should be apparent to a person of ordinary skill in the field, however, that the disclosed embodiments are exemplary and not exhaustive of all possible embodiments.

For the purposes of this disclosure, an information handling system may include an instrumentality or aggregate of instrumentalities operable to compute, classify, process, transmit, receive, retrieve, originate, switch, store, display, manifest, detect, record, reproduce, handle, or utilize various forms of information, intelligence, or data for business, scientific, control, entertainment, or other purposes. For example, an information handling system may be a personal computer, a PDA, a consumer electronic device, a network storage device, or another suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various input and output (I/O) devices, such as a keyboard, a mouse, and a video display. The information handling system may also include one or more buses operable to transmit communication between the various hardware components.

For the purposes of this disclosure, computer-readable media may include an instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory (SSD); as well as communications media such wires, optical fibers, microwaves, radio waves, and other electromagnetic and/or optical carriers; and/or any combination of the foregoing.

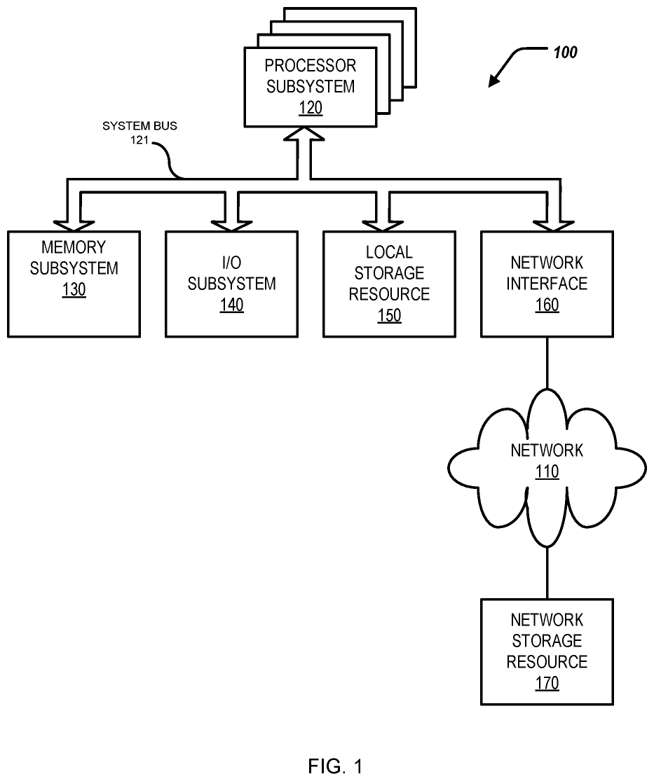

Particular embodiments are best understood by reference to FIGS. 1-8 wherein like numbers are used to indicate like and corresponding parts.

Turning now to the drawings, FIG. 1 illustrates a block diagram depicting selected elements of an information handling system 100 in accordance with some embodiments of the present disclosure. In various embodiments, information handling system 100 may represent different types of portable information handling systems, such as, display devices, head mounted displays, head mount display systems, smart phones, tablet computers, notebook computers, media players, digital cameras, 2-in-1 tablet-laptop combination computers, and wireless organizers, or other types of portable information handling systems. In one or more embodiments, information handling system 100 may also represent other types of information handling systems, including desktop computers, server systems, controllers, and microcontroller units, among other types of information handling systems. Components of information handling system 100 may include, but are not limited to, a processor subsystem 120, which may comprise one or more processors, and system bus 121 that communicatively couples various system components to processor subsystem 120 including, for example, a memory subsystem 130, an I/O subsystem 140, a local storage resource 150, and a network interface 160. System bus 121 may represent a variety of suitable types of bus structures, e.g., a memory bus, a peripheral bus, or a local bus using various bus architectures in selected embodiments. For example, such architectures may include, but are not limited to, Micro Channel Architecture (MCA) bus, Industry Standard Architecture (ISA) bus, Enhanced ISA (EISA) bus, Peripheral Component Interconnect (PCI) bus, PCI-Express bus, HyperTransport (HT) bus, and Video Electronics Standards Association (VESA) local bus.

As depicted in FIG. 1, processor subsystem 120 may comprise a system, device, or apparatus operable to interpret and/or execute program instructions and/or process data, and may include a microprocessor, microcontroller, digital signal processor (DSP), application specific integrated circuit (ASIC), or another digital or analog circuitry configured to interpret and/or execute program instructions and/or process data. In some embodiments, processor subsystem 120 may interpret and/or execute program instructions and/or process data stored locally (e.g., in memory subsystem 130 and/or another component of information handling system). In the same or alternative embodiments, processor subsystem 120 may interpret and/or execute program instructions and/or process data stored remotely (e.g., in network storage resource 170).

Also in FIG. 1, memory subsystem 130 may comprise a system, device, or apparatus operable to retain and/or retrieve program instructions and/or data for a period of time (e.g., computer-readable media). Memory subsystem 130 may comprise random access memory (RAM), electrically erasable programmable read-only memory (EEPROM), a PCMCIA card, flash memory, magnetic storage, opto-magnetic storage, and/or a suitable selection and/or array of volatile or non-volatile memory that retains data after power to its associated information handling system, such as system 100, is powered down.

In information handling system 100, I/O subsystem 140 may comprise a system, device, or apparatus generally operable to receive and/or transmit data to/from/within information handling system 100. I/O subsystem 140 may represent, for example, a variety of communication interfaces, graphics interfaces, video interfaces, user input interfaces, and/or peripheral interfaces. In various embodiments, I/O subsystem 140 may be used to support various peripheral devices, such as a touch panel, a display adapter, a keyboard, an accelerometer, a touch pad, a gyroscope, an IR sensor, a microphone, a sensor, or a camera, or another type of peripheral device.

Local storage resource 150 may comprise computer-readable media (e.g., hard disk drive, floppy disk drive, CD-ROM, and/or other type of rotating storage media, flash memory, EEPROM, and/or another type of solid state storage media) and may be generally operable to store instructions and/or data. Likewise, the network storage resource may comprise computer-readable media (e.g., hard disk drive, floppy disk drive, CD-ROM, and/or other type of rotating storage media, flash memory, EEPROM, and/or other type of solid state storage media) and may be generally operable to store instructions and/or data.

In FIG. 1, network interface 160 may be a suitable system, apparatus, or device operable to serve as an interface between information handling system 100 and a network 110. Network interface 160 may enable information handling system 100 to communicate over network 110 using a suitable transmission protocol and/or standard, including, but not limited to, transmission protocols and/or standards enumerated below with respect to the discussion of network 110. In some embodiments, network interface 160 may be communicatively coupled via network 110 to a network storage resource 170. Network 110 may be a public network or a private (e.g. corporate) network. The network may be implemented as, or may be a part of, a storage area network (SAN), personal area network (PAN), local area network (LAN), a metropolitan area network (MAN), a wide area network (WAN), a wireless local area network (WLAN), a virtual private network (VPN), an intranet, the Internet or another appropriate architecture or system that facilitates the communication of signals, data and/or messages (generally referred to as data). Network interface 160 may enable wired and/or wireless communications (e.g., NFC or Bluetooth) to and/or from information handling system 100.

In particular embodiments, network 110 may include one or more routers for routing data between client information handling systems 100 and server information handling systems 100. A device (e.g., a client information handling system 100 or a server information handling system 100) on network 110 may be addressed by a corresponding network address including, for example, an Internet protocol (IP) address, an Internet name, a Windows Internet name service (WINS) name, a domain name or other system name. In particular embodiments, network 110 may include one or more logical groupings of network devices such as, for example, one or more sites (e.g. customer sites) or subnets. As an example, a corporate network may include potentially thousands of offices or branches, each with its own subnet (or multiple subnets) having many devices. One or more client information handling systems 100 may communicate with one or more server information handling systems 100 via any suitable connection including, for example, a modem connection, a LAN connection including the Ethernet or a broadband WAN connection including DSL, Cable, Ti, T3, Fiber Optics, Wi-Fi, or a mobile network connection including GSM, GPRS, 3G, or WiMax.

Network 110 may transmit data using a desired storage and/or communication protocol, including, but not limited to, Fibre Channel, Frame Relay, Asynchronous Transfer Mode (ATM), Internet protocol (IP), other packet-based protocol, small computer system interface (SCSI), Internet SCSI (iSCSI), Serial Attached SCSI (SAS) or another transport that operates with the SCSI protocol, advanced technology attachment (ATA), serial ATA (SATA), advanced technology attachment packet interface (ATAPI), serial storage architecture (SSA), integrated drive electronics (IDE), and/or any combination thereof. Network 110 and its various components may be implemented using hardware, software, or any combination thereof.

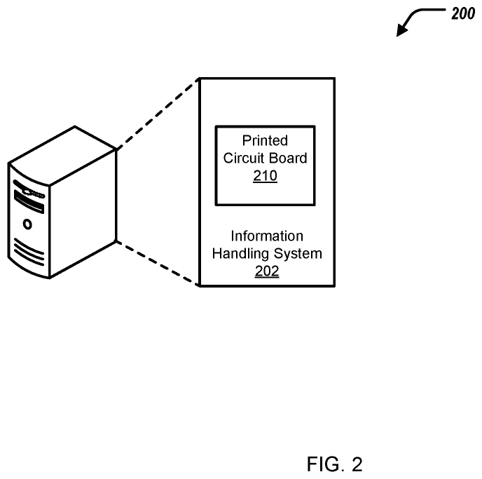

Turning to FIG. 2, FIG. 2 illustrates an environment 200 including an information handling system 202. The information handling system 202 can include a printed circuit board (PCB) 210. In some examples, the information handling system 202 is similar to, or includes, the information handling system 100 of FIG. 1.

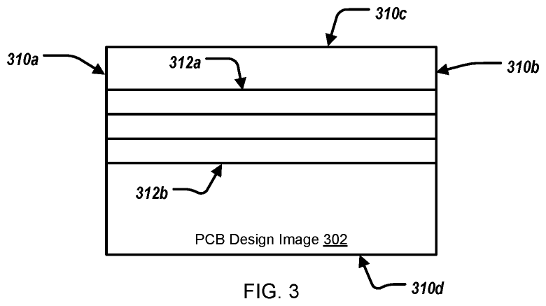

FIG. 3 illustrates a simplified top down view of a PCB design image 302 used in forming the PCB 210. In some examples, the PCB design image 302 can be a Gerber format PCB design image 302. The PCB design image 302 can include a first side 310a, a second side 310b, a third side 310c, and a fourth side 310d (collectively referred to as sides 310). The first side 310a can be opposite to the second side 310b; and the third side 310c can be opposite to the fourth side 310d. The PCB design image 302 can include at least one differential pair of traces 312a, 312b (collectively referred to as traces 312). The traces 312 can extend between the first side 310a and the second side 310b.

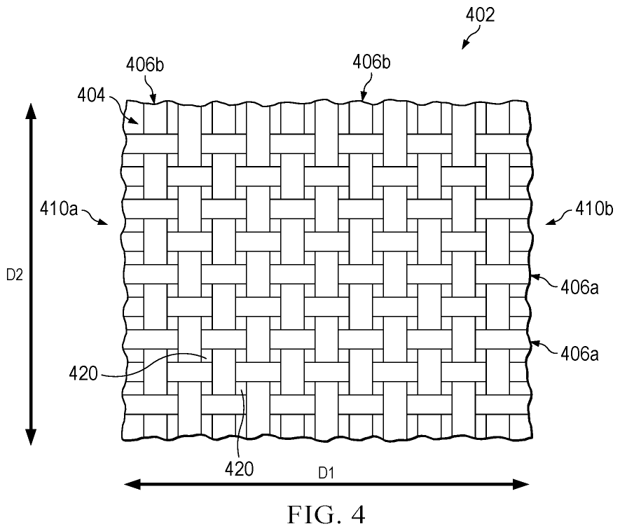

FIG. 4 illustrates a portion of a roll of a laminate sheet 402. The laminate sheet 402 can include a first side 410a and a second side 410b, the second side 410b opposite to the first side 410a. The laminate sheet 402 can include a fiber weave 404. The fiber weave 404 can include a plurality of fibers 406a and 406b (collectively referred to as fibers 406). The fibers 406a extend in a direction D1 between the first side 410a and the second side 410b. The fibers 406b can be orthogonal to the fibers 406a, and extend in a direction D2 orthogonal to the direction D1 that the fibers 406a extend. In some examples, the fibers 406 are glass, glass-based, formed from glass-type materials, and/or have characteristics similar to glass. In some examples, voids 420 can form between the junctions of the fibers 406.

In some examples, the laminate sheet 402 is used in formation of the PCB 210. To that end, a material, such as resin, can be placed at the voids 420. In some examples, a dielectric constant of the fibers 406 can differ from the dielectric constant of the resin at the voids 420. For example, the dielectric constant of the fibers 406 can be approximately 6-7 and the dielectric constant of the resin at the voids can be approximately 2.

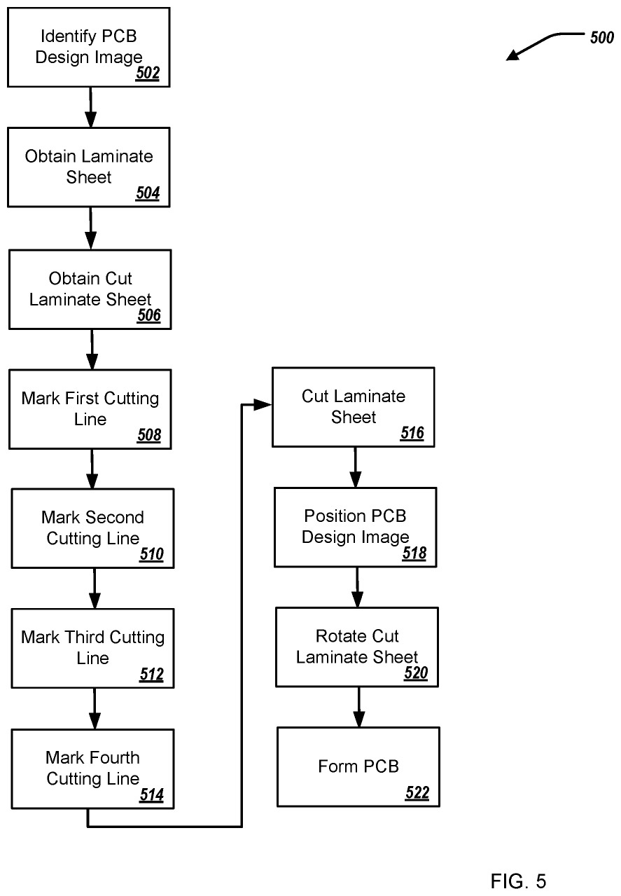

FIG. 5 illustrates a flowchart depicting selected elements of an embodiment of a method 500 for mitigating fiber weave effects in a printed circuit board. The method 500 may be performed by an information handling system, and with reference to FIGS. 1-4. It is noted that certain operations described in method 500 may be optional or may be rearranged in different embodiments.

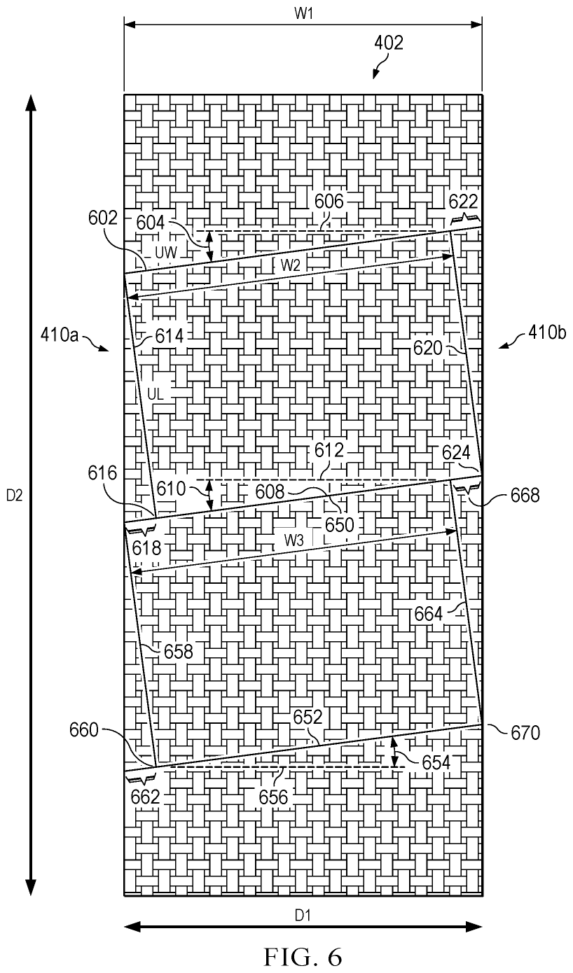

The PCB design image 302 is identified, at 502. The PCB design image 302 includes the pair of traces 312. The laminate sheet 402 is obtained, at 504. The laminate sheet 402 includes the fiber weave 404 of fibers 406. A cut laminate sheet from the laminate sheet 402 is obtained, at 506. Specifically, a first cutting line is marked, at 508. Referring to FIGS. 4 and 6, FIG. 6 illustrates the laminate sheet 402, including a first cutting line 602 extending between the first side 410a and the second side 410b of the laminate sheet 402. The first cutting line 602 extends between the first side 410a and the second side 410b at an angle 604 with respect to the direction D1 of the fibers 406a (for simplicity of illustration—shown by the angle 604 with respect to the line 606 that is parallel to the direction D1 of the fibers 406a). In some examples, the angle 604 is approximately 8 degrees.

A second cutting line is marked, at 510. Referring to FIGS. 4 and 6, the laminate sheet 402 includes a second cutting line 608 extending between the first side 410a and the second side 410b of the laminate sheet 402 and spaced-apart from the first cutting line 602. The second cutting line 608 extends between the first side 410a and the second side 410b at an angle 610 with respect to the direction D1 of the fibers 406a (for simplicity of illustration—shown by the angle 610 with respect to the line 612 that is parallel to the direction D1 of the fibers 406a). In some examples, the angle 604 is approximately 8 degrees. The second cutting line 608 is parallel to the first cutting line 602.

A third cutting line is marked, at 512. Referring to FIGS. 4 and 6, the laminate sheet 402 includes a third cutting line 614 extending between the first cutting line 602 and the second cutting line 608. The third cutting line 614 is perpendicular to the first cutting line 602 and the second cutting line 608. In some examples, the third cutting line 608 extends from the first cutting line 602 at the first side 410a of the laminate sheet 402 to the second cutting line 608. Further, an end 616 of the third cutting line 614 at the second cutting line 608 is spaced-apart from the first side 410a of the laminate sheet 402 a distance 618.

A fourth cutting line is marked, at 514. Referring to FIGS. 4 and 6, the laminate sheet 402 includes a fourth cutting line 620 extending between the first cutting line 602 and the second cutting line 608 and spaced-apart from the third cutting line 614. The fourth cutting line 620 is perpendicular to the first cutting line 602 and the second cutting line 608. The fourth cutting line 620 is parallel to the third cutting line 614. The fourth cutting line 620 extends from the first cutting line 602 spaced-apart from the second side 410b of the laminate sheet 402 a distance 622. The distance 622 is substantially the same as the distance 618. Further, an end 624 of the fourth cutting line 620 at the second cutting line 608 is at the second side 410b of the laminate sheet 402.

In some examples, the laminate sheet 402 has a first width W1 defined between the first side 410a and the second side 410b. In some examples, a second width W2 can be defined between the third cutting line 614 and the fourth cutting line 620. In some examples, the second width W2 is less than the first width W1.

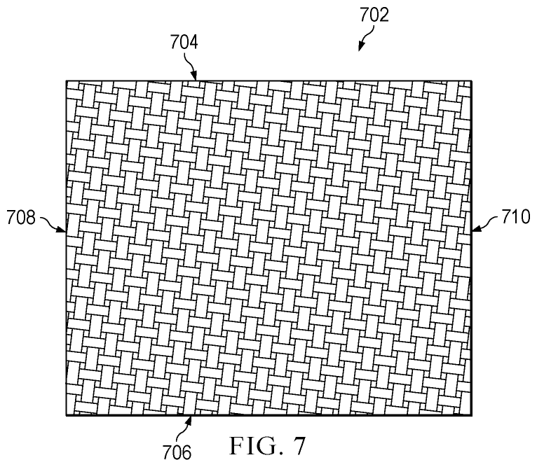

The laminate sheet 402 is cut, at 516. Specifically, the laminate sheet 402 is cut at the first cutting line 602, the second cutting line 608, the third cutting line 614, and the fourth cutting line 620 to form a cut laminate sheet 702, as shown in FIG. 7. In particular, the laminate sheet 402 is cut at the first cutting line 602, the second cutting line 608, the third cutting line 614, and the fourth cutting line 620 to form a first side 704, a second side 706, a third side 708, and a fourth side 710, respectively, of the cut laminate sheet 702.

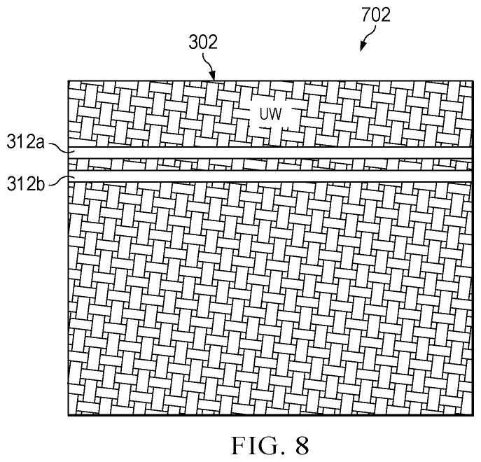

The PCB design image 302 is positioned in superimposition with the cut laminate sheet 702, at 518. The cut laminate sheet 702 is rotated, at 520. Specifically, the cut laminate sheet 702 is rotated such that each of the sides of the laminate sheet 702 are aligned with a respective side of the PCB design image 302. FIG. 8 illustrates the PCB design image 302 in superimposition with the rotated cut laminate sheet 702. In particular, referring to FIGS. 3, 7, and 8, the cut laminate sheet 702 is rotated such that, as shown in FIG. 8, the first side 704 of the cut laminate sheet 702 is aligned with the third side 310c of the PCB design image 302; the second side 706 of the cut laminate sheet 702 is aligned with the fourth side 310d of the PCB design image 302; the third side 708 of the cut laminate sheet 702 is aligned with the first side 310a of the PCB design image; and the fourth side 710 of the cut laminate sheet 702 is aligned with the second side 310b of the PCB design image.

Referring to FIGS. 7 and 8, in some examples, the cut laminate sheet 702 is rotated such that the each of the sides of the cut laminate sheet 702 are aligned with a respective side of the PCB design image 302 and the differential pair of traces 312 extend between the third side 708 and the fourth side 710 of the cut laminate sheet 702 at the angle 606 (or 612) with respect to the fibers 406. Thus, by rotating the cut laminate sheet 702 with respect to the PCB design image 302, fiber weave effect is minimized and/or avoided.

The PCB 210 is formed, at 522. Specifically, the PCB 210 is formed including the traces 312 on the cut laminate sheet 702 based on the rotation of the cut laminate sheet 702 with respect to the PCB design image 302 and the alignment between the cut laminate sheet 702 and the PCB design image 302. That is, when the cut laminate sheet 702 is rotated with respect to the PCB design image 302 such that the differential pair of traces 312 extend between the third side 708 and the fourth side 710 of the cut laminate sheet 702 at the angle 606 (or the angle 612) with respect to the fibers 406a, the PCB 210 can be formed to include the traces 312 at such the angle with respect to the fibers 406a based on the PCB design image 302.

To that end, by forming the PCB 210 to include the traces 312 at such the angle with respect to the fibers 406a based on the PCB design image 302, propagation delays of the traces 312 can minimized.

In some examples, the cut laminate sheet 702 includes a copper sheet attached. The PCB 210 is formed by transferring the PCB design image 302 to the cut laminate sheet 702 and the cooper sheet, and then etched. This process can be repeated for multiple cut laminate sheets 702 and PCB design images 302, such that multiple laminates are laminated together to form multi-layered PCBs.

In some examples, an additional cut laminate sheet can be formed from the laminate sheet 402. Specifically, referring to FIG. 3, an additional PCB design image is identified. In some examples, the additional PCB design image differs from the PCB design image 302. In some examples, the additional PCB design image is similar or substantially the same as the PCB design image 302. For simplicity of description, the additional PCB design image is described with reference to the PCB design image 302.

Referring to FIGS. 4 and 6, an additional cut laminate sheet from the laminate sheet 402 is obtained. Specifically, a fifth cutting line 650 is marked. The fifth cutting line 650 extends between the first side 410a and the second side 410b of the laminate sheet 402. The fifth cutting line 650 extends between the first side 410a and the second side 410b at the angle 610 with respect to the direction D1 of the fibers 406a. In some examples, the fifth cutting line 650 is the same as the second cutting line 608.

A sixth cutting line 652 is marked. The sixth cutting line 652 extending between the first side 410a and the second side 410b of the laminate sheet 402 and spaced-apart from the fifth cutting line 650. The sixth cutting line 652 extends between the first side 410a and the second side 410b at an angle 654 with respect to the direction D1 of the fibers 406a (for simplicity of illustration—shown by the angle 654 with respect to a line 656 that is parallel to the direction D1 of the fibers 406a). In some examples, the angle 656 is approximately 8 degrees. The sixth cutting line 652 is parallel to the fifth cutting line 650.

A seventh cutting line 658 is marked. The seventh cutting line 658 extends between the fifth cutting line 650 and the sixth cutting line 652. The seventh cutting line 658 is perpendicular to the fifth cutting line 650 and the sixth cutting line 652. In some examples, the seventh cutting line 658 extends from the fifth cutting line 650 at the first side 410a of the laminate sheet 402 to the sixth cutting line 652. Further, an end 660 of the seventh cutting line 658 at the sixth cutting line 652 is spaced-apart from the first side 410a of the laminate sheet 402 a distance 662. In some examples, the distance 662 is the same as the distance 618.

An eighth cutting line 664 is marked. The eighth cutting line 664 extends between the fifth cutting line 650 and the sixth cutting line 652. The fourth eighth line 664 is perpendicular to the fifth cutting line 650 and the sixth cutting line 652. The eighth cutting line 664 is parallel to the seventh cutting line 658 and spaced-apart from the seventh cutting line 658. The eighth cutting line 664 extends from the fifth cutting line 650 spaced-apart from the second side 410b of the laminate sheet 402 a distance 668. The distance 668 is substantially the same as the distance 622. Further, an end 670 of the eighth cutting line 664 at the sixth cutting line 652 is at the second side 410b of the laminate sheet 402.

In some examples, a third width W3 can be defined between the seventh cutting line 658 and the eighth cutting line 664. In some examples, the third width W3 is less than the first width W1. In some examples, the third width W3 is the same as the second width W2.

The laminate sheet 402 is cut at the fifth cutting line 650, the sixth cutting line 652, the seventh cutting line 658, and the eighth cutting line 664 to form an additional cut laminate sheet, similar to the cut laminate sheet 702, as shown in FIG. 7.

The PCB design image 302 is positioned in superimposition with the additional cut laminate sheet. The additional cut laminate sheet is rotated. Specifically, the additional cut laminate sheet is rotated such that each of the sides of the additional cut laminate sheet are aligned with a respective side of the PCB design image 302, similar to that mentioned above with respect to the cut laminate sheet 702 and the PCB design image 302.

In some examples, the additional cut laminate sheet is rotated such that the each of the sides of the additional cut laminate sheet are aligned with a respective side of the PCB design image 302 and the differential pair of traces 312 extend at the angle 612 (or the angle 654) with respect to the fibers 406a. Thus, by rotating the additional cut laminate with respect to the PCB design image 302, fiber weave effect is minimized and/or avoided.

An additional PCB is formed, similar to the PCB 210. Specifically, the additional PCB is formed including the traces 312 on the additional cut laminate sheet based on the rotation of the additional cut laminate sheet with respect to the PCB design image 302 and the alignment between the additional cut laminate sheet and the PCB design image 302. That is, when the additional cut laminate sheet is rotated with respect to the PCB design image 302 such that the differential pair of traces 312 extend at the angle 612 (or 654) with respect to the fibers 406a, the additional PCB can be formed to include the traces 312 at such the angle with respect to the fibers 406a based on the PCB design image 302.

To that end, by forming the additional PCB to include the traces 312 at such the angle with respect to the fibers 406a based on the PCB design image 302, propagation delays of the traces 312 can minimized.

The above disclosed subject matter is to be considered illustrative, and not restrictive, and the appended claims are intended to cover all such modifications, enhancements, and other embodiments which fall within the true spirit and scope of the present disclosure. Thus, to the maximum extent allowed by law, the scope of the present disclosure is to be determined by the broadest permissible interpretation of the following claims and their equivalents, and shall not be restricted or limited by the foregoing detailed description.

Herein, “or” is inclusive and not exclusive, unless expressly indicated otherwise or indicated otherwise by context. Therefore, herein, “A or B” means “A, B, or both,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated other-wise by context.

The scope of this disclosure encompasses all changes, substitutions, variations, alterations, and modifications to the example embodiments described or illustrated herein that a person having ordinary skill in the art would comprehend. The scope of this disclosure is not limited to the example embodiments described or illustrated herein. Moreover, although this disclosure describes and illustrates respective embodiments herein as including particular components, elements, features, functions, operations, or steps, any of these embodiments may include any combination or permutation of any of the components, elements, features, functions, operations, or steps described or illustrated anywhere herein that a person having ordinary skill in the art would comprehend. Furthermore, reference in the appended claims to an apparatus or system or a component of an apparatus or system being adapted to, arranged to, capable of, configured to, enabled to, operable to, or operative to perform a particular function encompasses that apparatus, system, component, whether or not it or that particular function is activated, turned on, or unlocked, as long as that apparatus, system, or component is so adapted, arranged, capable, configured, enabled, operable, or operative.

What is claimed is:

1. A method of mitigating fiber weave effect, comprising:
obtaining a laminate sheet, the laminate sheet including a fiber weave of fibers extending in a direction between a first side of the laminate sheet and a second side of the laminate sheet, the first side of the laminate sheet opposite to the second side of the laminate sheet;
obtaining a cut laminate sheet from the laminate sheet, the laminate sheet including a first side and a second side opposite to the first side, the obtaining including:
marking a first cutting line between the first side and the second side of the laminate sheet, the first cutting line at an angle with respect to the direction of the fibers of the laminate sheet;
marking a second cutting line between the first side and the second side of the laminate sheet, the second cutting line spaced-apart from the first cutting line and parallel to the first cutting line;
marking a third cutting line extending between the first and the second cutting lines, the third cutting line perpendicular to the first and the second cutting lines;
marking a fourth cutting line extending between the first and the second cutting lines, the fourth cutting line spaced-apart from the third cutting line and parallel to the third cutting line;
cutting the laminate sheet at the first, second, third, and fourth cutting lines to form first, second, third, and four sides, respectively, of the cut laminate sheet;
positioning a printed circuit board (PCB) design image in superimposition with the cut laminate sheet;
rotating the cut laminate sheet such that each of the sides of the cut laminate sheet are aligned with a respective side of the PCB design image; and
forming the PCB on the cut laminate sheet based on the rotation of the cut laminate sheet with respect to the PCB design image and the alignment between the cut laminate sheet and the PCB design image.

2. The method of claim 1, wherein marking the first cutting line includes marking the first cutting line such that the angle with respect to the direction of the fibers of the laminate sheet is approximately 8 degrees.

3. The method of claim 1, wherein a width distance between the third cutting line and the fourth cutting line of the cut laminate sheet is less than a width distance between the first side and the second side of the laminate sheet.

4. The method of claim 1, wherein the third cutting line extends from the first cutting line at the first side of the laminate sheet to the second cutting line, wherein an end of the third cutting line at the second cutting line is spaced-apart from the first side of the laminate sheet a distance.

5. The method of claim 4, wherein the fourth cutting line extends from the first cutting line, spaced-apart from the second side of the laminate sheet the distance, to the second cutting line, wherein an end of the fourth cutting line at the second cutting line is at the second side of the laminate sheet.

6. The method of claim 1,
wherein the PCB design image includes at least one differential pair of traces extending between a first side of the PCB design image and a second side of the PCB design image, the second side of the PCB design image opposite to the first side of the PCB design image,
wherein the PCB design image includes a third side and a fourth side extending between the first and the second sides of the PCB design image, the third side of the PCB design image opposite to the fourth side of the PCB design image,
wherein cutting the laminate sheet further includes:
cutting the laminate sheet at the first cutting line to form the first side of the cut laminate sheet;
cutting the laminate sheet at the second cutting line to form the second side of the cut laminate sheet;
cutting the laminate sheet at the third cutting line to form the third side of the cut laminate sheet;
cutting the laminate sheet at the fourth cutting line to form the fourth side of the cut laminate sheet,
wherein rotating the cut laminate sheet further includes:
rotating the cut laminate sheet such that:
the first side of the cut laminate sheet is aligned with the third side of the PCB design image;
the second side of the cut laminate sheet is aligned with the fourth side of the PCB design image;
the third side of the cut laminate sheet is aligned with the first side of the PCB design image; and
the fourth side of the cut laminate sheet is aligned with the second side of the PCB design image.

7. The method of claim 6 wherein rotating the cut laminate sheet further includes rotating the cut laminate sheet such that each of the sides of the cut laminate sheet are aligned with a respective side of the PCB design image and the differential pair of traces extend between the third side and the fourth side of the cut laminate sheet at the angle with respect to the fibers of the cut laminate sheet.

8. The method of claim 1, after obtaining the cut laminate sheet, the method further including:
obtaining an additional cut laminate sheet from the laminate sheet, the additional laminate sheet including a first side and a second side opposite to the first side, the obtaining including:
marking a fifth cutting line between the first side and the second side of the laminate sheet, the fifth cutting line at the angle with respect to the direction of the fibers of the laminate sheet;
marking a sixth cutting line between the first side and the second side of the laminate sheet, the sixth cutting line spaced-apart from the fifth cutting line and parallel to the fifth cutting line;
marking a seventh cutting line extending between the fifth and the sixth cutting lines, the seventh cutting line perpendicular to the fifth and the sixth cutting lines;
marking an eighth cutting line extending between the fifth and the sixth cutting lines, the eighth cutting line spaced-apart from the seventh cutting line and parallel to the seventh cutting line;
cutting the laminate sheet at the fifth, sixth, seventh, and eighth cutting lines to form fifth, sixth, seventh, and eighth sides, respectively, of the additional cut laminate sheet;
positioning the PCB design image in superimposition with the additional cut laminate sheet;
rotating the additional cut laminate sheet such that each of the sides of the additional cut laminate sheet are aligned with a respective side of the PCB design image; and
forming an additional PCB on the additional cut laminate sheet based on the rotation of the additional cut laminate sheet with respect to the PCB design image and the alignment between the additional cut laminate and the PCB design image.

9. The method of claim 8, wherein the fifth cutting line is the same as the fourth cutting line.

10. The method of claim 1, after obtaining the cut laminate sheet, the method further including:
identifying an additional PCB design image, the additional PCB design image including at least one differential pair of traces extending between a first side of the additional PCB design image and a second side of the additional PCB design image, the second side of the additional PCB design image opposite to the first side of the additional PCB design image;
obtaining an additional cut laminate sheet from the laminate sheet, the additional laminate sheet including a first side and a second side opposite to the first side, the obtaining including:
marking a fifth cutting line between the first side and the second side of the laminate sheet, the fifth cutting line at the angle with respect to the direction of the fibers of the laminate sheet;
marking a sixth cutting line between the first side and the second side of the laminate sheet, the sixth cutting line spaced-apart from the fifth cutting line and parallel to the fifth cutting line;
marking a seventh cutting line extending between the fifth and the sixth cutting lines, the seventh cutting line perpendicular to the fifth and the sixth cutting lines;
marking an eighth cutting line extending between the fifth and the sixth cutting lines, the eighth cutting line spaced-apart from the seventh cutting line and parallel to the seventh cutting line;
cutting the laminate sheet at the fifth, sixth, seventh, and eighth cutting lines to form fifth, sixth, seventh, and eighth sides, respectively, of the cut laminate sheet;
positioning the PCB design image in superimposition with the additional cut laminate sheet;
rotating the additional cut laminate sheet such that each of the sides of the additional cut laminate sheet are aligned with a respective side of the additional PCB design image; and
forming an additional PCB, including the differential pair of traces, on the additional cut laminate sheet based on the rotation of the additional cut laminate sheet with respect to the additional PCB design image and the alignment between the additional cut laminate and the additional PCB design image.

11. The method of claim 10, wherein the fifth cutting line is the same as the second cutting line.

12. The method of claim 10, wherein the additional PCB design image differs from the PCB design image.
